(19) United States
(12) Patent Application Publication
(10) Pub. No.: US 2025/0201759 A1
(43) Pub. Date: Jun. 19, 2025

(54) METHOD OF BONDING CHIPS AND A SYSTEM FOR PERFORMING THE METHOD

(71) Applicant: CANON KABUSHIKI KAISHA, Tokyo (JP)

(72) Inventor: Byung-Jin Choi, Austin, TX (US)

(21) Appl. No.: 18/542,365

(22) Filed: Dec. 15, 2023

(51) Int. Cl. H01L 23/00

(52) U.S. Cl. CPC H01L 24/80; H01L 24/74; H01L 2224/74; H01L 2224/8016; H01L 2224/8018; H01L 2224/80895; H01L 2224/80896

(57) ABSTRACT

A method for bonding chips includes actuating a plurality of bonding heads to cause a plurality of chips to bond to a bonding surface supported by a carriage, and during the bonding of the plurality of chips to the bonding surface, actuating a plurality of force applicators to collectively impart a net moment of force to the carriage about a center of rotation of the carriage that opposes a net moment of force collectively imparted to the carriage about the center of rotation of the carriage by the plurality of bonding heads.

### FIELD OF THE DISCLOSURE

The present disclosure relates to methods of bonding chips including collectively bonding multiple chips.

### RELATED ART

Advanced packaging technologies demand precise and accurate control and placement of chips. For increased productivity/throughput, it is desirable in the art to bond multiple source chips to a bonding surface using multiple bonding heads at the same time. However, even when actuating multiple bonding heads as close to the same time as possible, the chip on one of the bonding heads will invariably contact the bonding surface just prior to the other chips on the other bonding heads. This initial contact by one chip on one bonding head will cause the carriage supporting the bonding surface to tilt about a center of rotation. The tilting of the carriage about the center of rotation induces increased or instable alignment for the chips on the remaining bonding heads.

FIG. 10 shows a schematic side view of the bonding portion 1 of a bonding system in which the tilting about the center of rotation of a carriage occurs. The bonding portion 1 includes bonding heads 2 coupled with a bridge 3. Below the bonding heads 2 is a carriage 4 holding a substrate chuck 5 with a substrate 6. The carriage 4 rides on a base 8 via a bearing, where the bearing can be either air bearing or magnetically supported 7. FIG. 10 shows a moment when the bonding heads 2 have attempted to bond two chips 9 to a bonding surface 10 on the substrate 6. However, as noted above, even if it is attempted to bond the two chips 9 to the bonding surface 10 at the same time, invariably, one of the chips will contact the bonding surface 10 first. As shown in FIG. 10, when this happens, the carriage 4, including all of the structure it carries, will rotate in direction 11 about the center of rotation CR. This rotation causes an offset angle 12 that will negatively impact the alignment of the second chip that comes into contact with the bonding surface 10 after the first chip contacts the bonding surface 10. The rotation causes alignment errors for the bonding of the next chip. Such an additional error is difficult to compensate for as the tilt amount will vary depending on the bonding locations. In the system of FIG. 10, a tilt of the carriage 4 of greater than 0.2 μradians caused by the bonding process will result in an alignment error on the order of, for example, greater than 10 nm. The relationship between the alignment error and tilt may be a function of a distance in the bonding direction (Z-axis) between the center of rotation CR of the carriage 4.

Thus, there is a need in the art for a method and system for bonding multiple source chips to a bonding surface while eliminating or minimizing alignment error due to tilt about a center of rotation of the carriage.

### SUMMARY

A method for bonding chips includes actuating a plurality of bonding heads to cause a plurality of chips to bond to a bonding surface supported by a carriage, and during the bonding of the plurality of chips to the bonding surface, actuating a plurality of force applicators to collectively impart a net moment of force to the carriage about a center of rotation of the carriage that opposes a net moment of force collectively imparted to the carriage about the center of rotation of the carriage by the plurality of bonding heads.

A system for bonding chips includes a plurality of bonding heads, a plurality of force applicators, a carriage having a center of rotation, one or more processors, and one or more memories storing instructions. When executed by the one or more processors, the instructions cause the system to actuate the plurality of bonding heads to cause a plurality of chips to bond to a bonding surface supported by the carriage, and during the bonding of the plurality of chips to the bonding surface, actuate the plurality of force applicators to collectively impart a net moment of force to the carriage about the center of rotation of the carriage that opposes a net moment of force collectively imparted to the carriage about the center of rotation by the plurality of bonding heads.

A method of manufacturing a plurality of articles, includes actuating a plurality of bonding heads to cause a plurality of chips to bond to a bonding surface of a substrate supported by a carriage, during the bonding of the plurality of chips to the bonding surface, actuating a plurality of force applicators to collectively impart a net moment of force to the carriage about a center of rotation of the carriage that opposes a net moment of force collectively imparted to the carriage about the center of rotation of the carriage by the plurality of bonding heads, and singulating the substrate to produce the plurality of articles.

### BRIEF DESCRIPTION OF THE DRAWINGS

Implementations are illustrated by way of example and are not limited in the accompanying figures.

FIG. 1 shows a schematic side view of a bonding system, in accordance with an example embodiment.

FIG. 2 shows a flowchart of a method for bonding chips using the bonding system of FIG. 1, in accordance with an example embodiment.

FIG. 3A shows a schematic enlarged view of a portion of FIG. 1, in accordance with an example embodiment.

FIG. 3B shows the enlarged view of a portion of FIG. 1 after a plurality of bonding heads have extended toward a substrate, in accordance with an example embodiment.

FIG. 3C shows the enlarged view of a portion of FIG. 1 after a plurality of chips on the bonding heads have reached the substrate, in accordance with an example embodiment.

FIG. 4 shows a schematic top view of the portion of FIG. 1 at the same moment shown in FIG. 3C, in accordance with an example embodiment.

FIG. 5 shows the schematic top view of FIG. 4, while additionally including force and location vectors, in accordance with an example embodiment.

FIG. 6 shows an enlarged side view of a portion of FIG. 3C, while additionally including force and location vectors, in accordance with an example embodiment.

FIG. 7A shows a timing chart of force applied by a plurality of bonding heads during a bonding process, in accordance with an example embodiment.

FIG. 7B shows a timing chart of force applied by a plurality of force applicators during the bonding process, in accordance with an example embodiment.

FIG. 7C shows a timing chart of the net moment of force collectively applied by the plurality of bonding heads and a net moment of force collectively applied by the plurality of force applicators in the X and Y dimensions during the bonding process, in accordance with an example embodiment.

FIG. 8A shows an enlarged schematic side view of a portion of FIG. 1 during a subsequent bonding process where a second set of chips are being bonded, in accordance with an example embodiment.

FIG. 8B shows a schematic top view of the same moment shown in FIG. 8A, in accordance with an example embodiment.

FIG. 9 is shows a schematic enlarged view of a portion of a bonding system, in accordance with another example embodiment.

FIG. 10 show a schematic side view of a related art bonding system in which a carriage is being tilted during a bonding process.

Skilled artisans appreciate that elements in the figures are illustrated for simplicity and clarity and have not necessarily been drawn to scale. For example, the dimensions of some of the elements in the figures can be exaggerated relative to other elements to help improve understanding of implementations of the invention.

### DETAILED DESCRIPTION

The following description in combination with the figures is provided to assist in understanding the teachings disclosed herein. The following discussion will focus on specific implementations and implementations of the teachings. This focus is provided to assist in describing the teachings and should not be interpreted as a limitation on the scope or applicability of the teachings.

Unless otherwise defined, all technical and scientific terms used herein have the same meaning as commonly understood by one of ordinary skill in the art to which this invention belongs. The materials, methods, and examples are illustrative only and not intended to be limiting. To the extent not described herein, many details regarding specific materials and processing acts are conventional and can be found in textbooks and other sources within the arts.

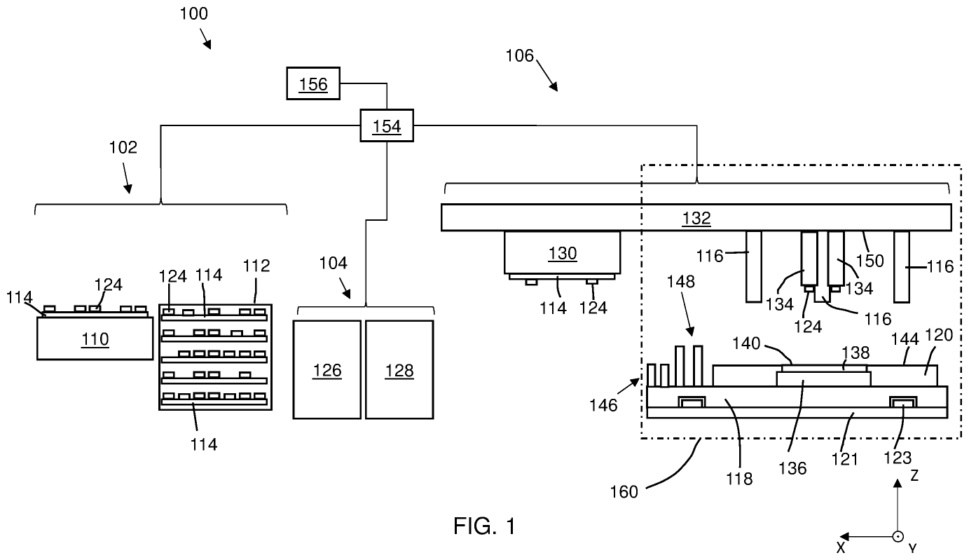

FIG. 1 shows a schematic side view of a bonding system 100 in accordance with an example embodiment. As shown in FIG. 1, the bonding system 100 includes a chip source section 102, a chip transfer and activation section 104, and a chip bonding section 106. The chip source section 102 is the portion of the overall bonding system 100 that contains the source chips that will be used in the bonding process. The chip transfer and activation section 104 is the portion of the overall bonding system 100 that transfers the chips from the chip source section 102 to the chip bonding section 106. In another configuration, the chip source section can be a separate apparatus. Similarly, the chip activation section can be a separate apparatus. The chip transfer and activation section 104 also activates the source chips so the source chips are ready for bonding. In an alternative embodiment, the activation section 104 activates the plurality of chips 124 prior to the chips being placed in the chip source section 102. The chip bonding section 106 receives chips that have been activated and then performs the bonding.

The chip source section 102 includes one or more sources for chips. For example, as shown in FIG. 1, the chip source section may include a substrate 114 held by a source chuck 110 with chips 124 thereon and/or may include a front opening unified/universal pod 112 (known in the art as a “FOUP”). The FOUP may include a plurality of the substrates 114 and chips 124. Other chip sources known in the art may be used in the chip source section 102 such as trays, adhesive tape in a frame, adhesive tape on a reel, adhesive layer on a stiff substrate, etc. As used herein, chip means an integrated circuit, also referred to as a microchip, a computer chip, etc. A chip may be defined as a small block of semiconducting material on which a given functional circuit is fabricated. In the context of a wafer/substrate that has been divided into individual chips, the chip is known is a die. The chip will typically carry a set of integrated electronic components and circuits formed on it by patterning, coating, etching, doping, plating, singulating, etc. The chip will typically have electrical functions such as: memory, logic, field programmable gate arrays (FPGA), accelerator circuits, application-specific integrated circuits (ASICs), security co-processors, graphics processing units (GPUs), machine learning circuits, specialized processors, controllers, devices, electrical circuits, arrays of passive components, etc. The chip may also be a micro-electromechanical systems (MEMS) device, an optical device, an electro-optical device, a micro-fluidic device, etc.

The chip transfer and activation section 104 includes a transfer robot 126 that is able to lift and carry a substrate 114 to a second substrate chuck 130 in the bonding section 106. As understood in the art, the transfer robot 126 generally includes a hand and a robot arm that provides the degrees of motion to lift, carry, and place a substrate from one location to another, such as from one substrate chuck to another or from a substrate storage location to a substrate chuck. The transfer robot 126 may be any suitable device known in the art, for example robots such as the wafer handling robot RR756L15 provided by Rorze Corporation of Fukuyama-shi, Hiroshima-ken, Japan. The chip transfer and activation device 104 further includes an activation device 128. The activation device 128 is a device that prepares the chips being transferred for hybrid bonding. Hybrid bonding is a chip bonding technique in which electrically insulating (e.g. silicon dioxide) chip surfaces with recessed metallic (e.g. copper) pads are brought into contact with each other. The metallic pads are aligned with each other, while the electrically insulating surfaces are bonded to each other via direct contact. Heat is then applied to the bonded structure which causes the metallic pads to expand more relative to the electrically insulating material and contact each other, thus forming electrical connections between the chips. In an example embodiment, the activation device 128 may include a fluid source that applies for example deionized water and possibly a plasma source that activates the surface of the chips prior to them being carried by the transfer robot 126. Due to the materials of the chips (i.e., dielectric), when the activated chip is brought into contact with another chip a fusion bond will occur between the dielectric surfaces of the two chips.

The bonding section 106 includes the second substrate chuck 130 for receiving the substrate 114 that has been carried by the transfer robot 126 and has chips that have been activated by the activation device 128. The second substrate chuck 130 is also referred herein as an intermediate substrate chuck. The bonding section 106 may include a bridge 132 to which the intermediate substrate chuck 130 is attached. The bonding section 106 also includes a plurality of bonding heads 134 attached to the bridge 132. In an embodiment, the bonding heads 134 may include a perimeter chuck region that holds the back surface of the chip 124 along the perimeter and a center pressure source that bows out a chip 124 held along the perimeter. In an embodiment, the bonding heads 134 may include one or more actuators that move the chip chuck in at least the Z direction towards a product substrate chuck 136.

The bonding heads 134 may include one or more additional actuators that move the chip chuck in at least one of five directions (x, y, tip, tilt, and rotation about the z axis The actuators may be voice coil motors, piezoelectric motors, linear motors, nut and screw motors, piezo-actuated stages, brushless DC motor stages, DC stepper motors, which are configured to move the chip chuck to and from the product substrate chuck 136 and also applied a controlled force to the chip when it is in contact with the bonding surface 140. The chip chuck may hold the chip to the chucking surface using: vacuum forces; electrostatic forces; electromagnetic forces; mechanical gripping forces; or any other method of releasably holding the chip to the chucking surface of the bonding head 134. The bonding section 106 further includes a product substrate chuck 136 holding a product substrate 138. The product substrate 138 has a bonding surface 140. The bonding surface 140 in the illustrated example embodiment is the upper surface of the product substrate 138. In another example embodiment, the bonding surface may be a surface of a chip already on the product substrate 138. That is, the bonding described herein may be used to bond source chips onto the surface of a product substrate and/or may be used to bond source chips to the surface of a product chip on the product substrate.

As shown in FIG. 1, the bonding system 106 further includes a carriage 142 that carries the product substrate chuck 136. The carriage 142 includes a support unit 118 and a frame. The support unit 118 rides on a base 121 via a bearing unit 123. The bearing unit 123 may be an air bearing, a mechanical bearing, or a magnetically levitated bearing that allows the support unit 118 to be moved smoothly along one or more guide rails that limit the motion of the support unit 118 in a particular direction. The support unit 118 supports the product substrate chuck 136 as well as a plurality of transfer heads 148 and a plurality of alignment heads 146, discussed below. The frame 120 has a central opening and surrounds the product substrate chuck 136. When the product substrate chuck 136 is holding the product substrate 138, the frame 120 may also surround the product substrate 138. The frame 120 may provide a uniform surface that helps control the flow air around the substrate during bonding. The support unit 118 may be attached to or be a part of a moving part of a multi-axis stage that moves the support unit under the bridge 132 in a controlled manner in one or more directions including x, y, z, θx, θy, and θz.

The bonding section 106 further includes a plurality of force applicators 116 that are carried by the carriage 142. Each force applicator of the plurality of force applicators 116 is a mechanism configured to impart a moment of force about center of rotation CR of the carriage 142. The moment of force is the tilting effect about the center of rotation produced by the force and calculated as the cross product of the force vector with a vector connecting the point at which the force is applied and the center of rotation CR. The center of rotation of the carriage 142 is determined by all of the structure of the carriage 142 as well as all of the structure that is carried by the carriage 142. That is, in an example embodiment, the center of rotation CR is determined by the support unit 118, the frame 120, the product substrate chuck 136, the product substrate 138 having a non-uniform distribution of mass, the alignment devices 146 and the transfer heads 148. The product substrate 138 may be made up of a plurality of chip/die that have been previously bonded to the product substrate 138. As the manufacturing process progresses, the distribution of mass on the product substrate will change over time, which will change the center of rotation CR. The center of rotation CR may be calculated by calculating the center of mass (centroid) of the carriage and everything attached to the carriage.

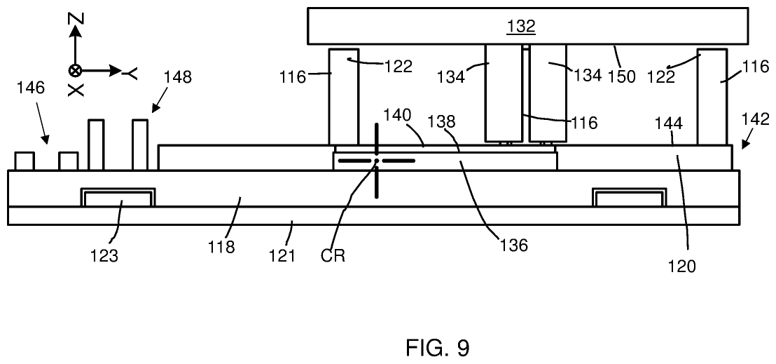

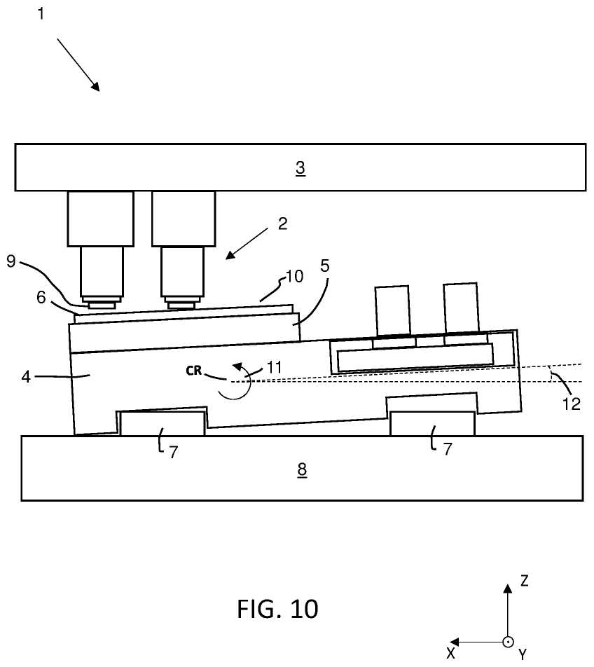

The force applicators may be located on the bridge 132 as illustrated in the example embodiment. The actuating end 122 of the force applicators 116 (i.e., the end of that is opposite to the attachment end) faces an actuating surface on which the force applicators 116 will apply the force. For example, in the illustrated embodiment of FIG. 1, the actuating surface on which the force applicators 116 will apply force is a surface 144 of the frame 120 that surrounds the product substrate chuck 136. Alternatively, the force applicators may be positioned on the frame 120 in the area surrounding the product substrate chuck 136 (FIG. 9 discussed below). In that case, the actuating surface on which the force applicators apply the force would be a surface 150 of or attached to the bridge 132. In yet another embodiment, one or more of the force applicators 116 may be on the bridge while one or more other force applicators may be on the carriage. In that case, the one or more force applicators on the bridge would apply force upon the surface 144 of the frame 120 while the one or more force applicators on the frame 120 would apply force upon the surface 150 of the bridge 132. In a case where one or more force applicators are mounted to the frame 120, the force applicators 116 on the frame 120 would also contribute to the center of rotation CR. That is, as noted above, the center of rotation CR of the carriage is determined by the carriage itself along with any additional components that the carriage carries.

The force applicator may be a non-contact force applicator that has a tendency to not create particles that would impact the bonding process. In one example embodiment the force applicators may have a gas nozzle configuration. The gas nozzle configuration includes a compressed gas blow nozzle with a fixed aperture, where the fixed aperture may be circular, for example. The compressed gas blow nozzle may be connected to a controller such as a pressure regulator and/or mass flow controller. The controller is connected to a compressed gas source. The compressed gas source may include a compressed fluid tank or a connection to an external compressed air source. The controller may be connected to a pump that increases the pressure of the gas. The gas may be clean dry air, nitrogen, a noble gas, or any gas that will not interfere with the bonding process. The gas nozzle may be positioned relative to the actuating surface being acted upon (i.e., surface 144 or surface 150) without the nozzle physically contacting the contacting surface. For example, the force applicator may be positioned such that a distance between the actuating surface being acted upon and the gas nozzle of the force applicator is less than 1 mm.

In another example embodiment, the force applicators may use magnetism to impart the moment of force on the carriage. For example, each force applicator may include an electromagnet facing the actuating surface being acted upon, where the actuating surface being acted upon is made of a material which is attracted to or repelled by the electromagnet. The surface 144 or the surface 150 may be made of the material that is attracted to or repelled by the electromagnet. The surface 144 of the frame 120 may be a separate plate made of the material that is attached to the frame 120 or the frame itself may be made of the material. Similarly, the surface 150 of the bridge 132 may be a separate plate made of the material that is attached to the bridge 132 or the bridge itself may be made of the material. By activating the electromagnet of the force applicator, the resulting repelling or attracting force on the actuating surface will impart the moment of force on the carriage about the center of rotation CR.

As noted above, the bonding section 106 may further include a plurality of alignment devices 146 and a plurality of transfer heads 148, all of which are also carried by the carriage 142. As shown in FIG. 1, the support unit 118 of the carriage 142 may support the alignment devices 148 and the transfer heads 148. Each of the plurality of transfer heads 148, may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the Z direction towards and away from the bridge 132. The plurality of alignment devices 146 are used to examine the alignment of chips on the plurality of bonding heads 134 after the chips have been transferred to the plurality of bonding heads 134. Each alignment device may be a microscope, a camera, an interferometer, or any sort of measuring device that is capable of measuring the position of each chip on a nanometer scale. The information provided by the plurality of alignment devices 146 will allow the operator to know whether each chip is at a target position within an acceptable amount of error. The plurality of alignment devices 146 may be any suitable device known in the art, for example a 20× microscope with 5 megapixel camera such as a CI-5MGMCL from Canon Inc., of Tokyo Japan. The plurality of transfer heads 148 are used to transfer the chips from the substrate 114 that is held by the intermediate substrate chuck 130 to the plurality of bonding heads 134. Each of the plurality of transfer heads 148 may include any one of a variety of methods of holding the chips including but not limited to: a Bernoulli chuck; a suction nozzle; an electrostatic chuck; an edge gripping chuck; a latching mechanism; or any method of releasably holding a chip. Each of the plurality of transfer heads 148, may include an actuator for moving in at least the Z direction towards and away from the bridge 132.

The number of bonding heads of the plurality of bonding heads is at least two but can be as many as 300. The number of bonding heads may be 2 to 300, 5 to 100, or 8 to 16, for example. The arrangement of the plurality of bonding heads may be in the form of columns and rows such as one by two, two by one, two by two, one by three, three by one, two by three, three by two, three by three, four by one, one by four, four by two, two by four, three by four, four by three, four by four, etc. In the illustrated example embodiment, the bonding heads are two by two, for a total of four bonding heads. The number and arrangement of transfer heads of the plurality of transfer heads may be the same as the number and arrangement of the bonding heads. Or the number and arrangement of transfer heads of the plurality of transfer heads can be larger than those of the bonding heads.

The bonding section 106 may further include a microscope (not shown) on the carriage 142 and a microscope (not shown) on the bridge 132. When present, the microscope would contribute to the location of the center of rotation CR of the carriage 142. The microscope on the carriage 142 is moveable along with the plurality of transfer heads 148, the product substrate chuck 136, and the plurality of alignment devices 146. The microscope on the carriage is aimed upwardly in a direction toward the intermediate substrate chuck 130. The microscope on the carriage functions to measure positions of the plurality of chips on the substrate 114. The microscope on the bridge faces downward in a direction toward the product substrate chuck 136. The microscope on the bridge functions to measure positions of the chips on the product substrate 138. Each of the microscopes may be suitable device known in the art, for example a 20× microscope with a 5 megapixel camera such as a CI-5MGMCL from Canon Inc., of Tokyo Japan.

The bonding system 100 may be regulated, controlled, and/or directed by one or more processors 154 (controller) in communication with one or more components and/or subsystems such as the chip source section 102, the chip transfer and activation section 104, the bonding section 106, the source chuck 110, the FOUP 112, the transfer robot 126, the activation device 128, the intermediate substrate chuck 130, the plurality of bonding heads 134, the plurality of force applicators 116, the product substrate chuck 136, the carriage 142, the plurality of alignment devices 146, the plurality of transfer heads 148, and any microscopes. The processor 154 may operate based on instructions in a computer readable program stored in a non-transitory computer memory 156. The processor 154 may be or include one or more of a CPU, MPU, GPU, ASIC, FPGA, DSP, and a general-purpose computer. The processor 154 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. All of the steps described herein may be executed by the processor 154.

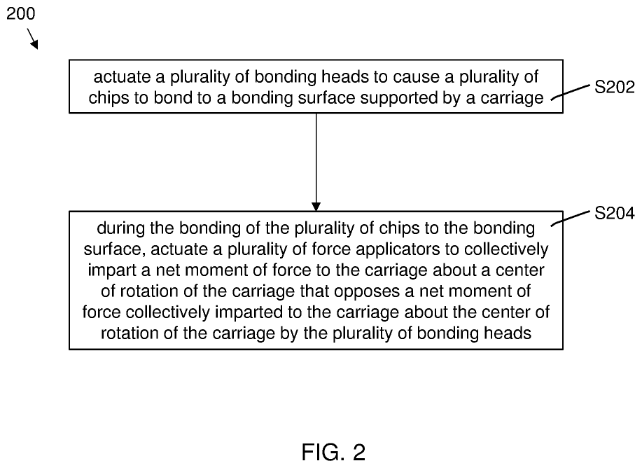

FIG. 2 shows a flowchart of a method for bonding chips 200 using the bonding system 100. The method for bonding chips 200 begins with step S202 where a plurality of bonding heads are actuated to cause a plurality of chips to bond to a bonding surface supported by a carriage. However, several steps may occur prior to the first step shown in FIG. 2 that may also be part of the bonding method. For example, the following additional steps may be performed prior to step S202. First, desired chip information may be received, including where the chips are to be placed on the bonding surface. After receiving the chip information, if not already activated, the transfer robot 126 may carry a source substrate 114 through the activation device 128 to activate the chips in the manner described above, after which the source substrate 114 is received by the chip bonding section 106. After passing through the activation device 128, with the chips activated, the transfer robot 126 will then carry the source substrate 114 to the second substrate chuck 130 of the chip bonding section 106. In an alternative embodiment, the chips on the source substrate 114 are already activated and are transferred directly to the bonding section 106 from the chip source section 102.

The source substrate 114, having the activated chips 124, may then be chucked to the second substrate chuck 130. Next, once the source substrate 114 having the activated chips 124 has been mounted to the second substrate chuck 130, a microscope may be used to measure the position of the plurality of chips 124. This step may be performed by moving the carriage 142 until the microscope is beneath the plurality of chips 124. If the feedback from the first microscope shows that the certain chips of the plurality of chips 124 are outside of an acceptable amount of error, then a replacement substrate 114 would need to be prepared. If the feedback from the microscope shows that the plurality of chips 124 are located at the proper positions within an acceptable amount of error, the method may proceed.

A first set of chips from the source substrate 114 may be then transferred to the plurality of bonding heads 134. This step may be performed by first moving the carriage 142 until the plurality of transfer heads 148 are beneath the plurality of chips 124. The plurality of transfer heads 148 may include the same number of heads with the same pitches as the plurality of bonding heads 134. The plurality of transfer heads 148 are configured to mirror the plurality of bonding heads 134 so that the plurality of transfer heads 148 can transfer up to the same number of chips that the plurality of bonding heads are capable of bonding in a single bonding step. The plurality of transfer heads 148 may pick up a first set of chips from the source substrate 114 by activating a vacuum force, for example. The plurality of transfer heads 148 may maintain the vacuum force while the plurality of transfer heads 148 carrying the first set of chips are moved via the carriage 142 to a position underneath the plurality of bonding heads 134. Either the plurality of transfer heads 148 or the plurality of bonding heads 134 moves toward the other (or both move simultaneously) until the first set of chips are at a position to be transferred to the plurality of bonding heads 134. Once close enough, the vacuum force on the plurality of transfer heads 148 may be terminated and a vacuum force of the plurality of bonding heads 134 may be activated, thereby transferring the first set of chips to the plurality of bonding heads 134. After the chips 124 (first set of chips) have been transferred to the bonding heads, the carriage 142 may be moved to position the product substrate 138 so that the bonding surface 140 arrived at a predetermined location relative to the bonding heads 134 holding the first set of chips. That is, the processor 154 may receive/process information regarding where the chips 124 of the current bonding procedure (first set of chips) should be placed on the bonding surface 140 and based on this information, the processor will cause the carriage 142 to move such that the chips 124 held by the bonding heads 134 are properly located in the X/Y dimensions. The moment after all these steps have been performed, which is just prior to step S202, is the moment shown in FIG. 1. That is, at the moment shown in FIG. 1, each of the bonding heads 134 is holding a chip 124 that is located at the predetermined location above the bonding surface 140, and the system ready for the bonding method to proceed. At this moment, in the illustrated embodiment, the force applicators 116 are positioned outward of the bonding heads 134 and face the frame 120 of the carriage 142.

With the above-noted initial steps completed, the bonding method 200 is ready to begin the above-noted step S202 of actuating a plurality of bonding heads to cause a plurality of chips to bond to a bonding surface supported by a carriage.

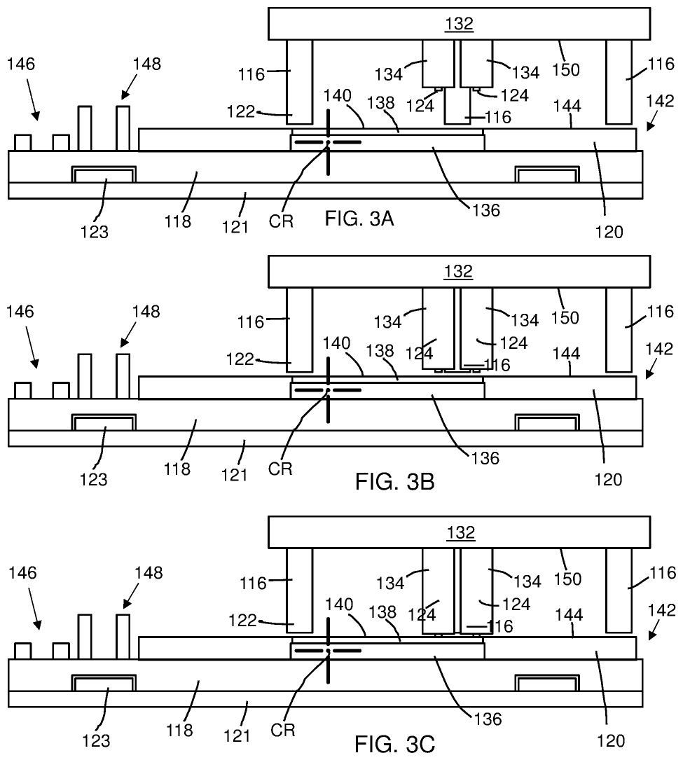

FIG. 3A shows an enlarged view of the portion 160 in a first example bonding process where a first set of chips 124 are to be bonded. As shown in FIG. 3A the bonding heads 134 are located at positions above the bonding surface 140 that is near the edge of the substrate 138. That is, in this first instance where a first set up chips are to be bonded, the carriage 142 has already been moved so that chips 124 are located at the predetermined position above the bonding surface 140. In this first case, the predetermined position is near the edge of the product substrate 138. Thus, as shown in FIG. 3A, prior to performing step S202, each of the bonding heads 134 have one of the chips 124, and the bonding heads 134 are above the bonding surface 140. While all of the bonding heads are facing the substrate in the illustrated embodiment, in some instances not all of the bonding heads are facing the bonding surface. While the benefit of the bonding method 200 is primarily achieved when there are at least two bonding heads actively being used, as long as at least one of the bonding heads is being used, the bonding method 200 can still be performed. In a case where less than all of the available bonding heads are not facing the bonding surface, those not facing the bonding surface will not be actuated and the at least one (preferably two or more) bonding head facing the bonding surface will be actuated.

At the moment shown in FIG. 3A, the force applicators 116 are not yet actuated because there has not yet been any contact of a chip 124 with the bonding surface 140. When the bonding heads 134 are positioned for bonding, at least two of the force applicators 116 are positioned to face the surface 144. That is, while more than two force applicators are preferably present (e.g., three in the illustrated example embodiment), the force applicators are mounted at positions on the bridge such that no matter where the bonding heads are located relative to bonding surface during a particular bonding process, at least two of the force applicators are able to act upon the surface 144. In many positions of the bonding heads relative to the bonding surface, more than two (e.g., three in the illustrated embodiment) will be facing the surface 144 and are available to impart the force on the surface 144. The number of force applicators may be 2 to 30, more preferably 3 to 5.

After being placed in the position shown in FIG. 3A, the bonding heads 134 may be actuated such that the chips 124 move in the Z direction toward the bonding surface 140. FIG. 3B shows the same enlarged view of FIG. 3A at a moment just before the chips 124 have come into contact with the bonding surface 140. At this moment, the force applicators 116 are still not yet actuated because none of the chips have come into contact with the bonding surface 140.

FIG. 3C shows the same enlarged view of FIG. 3A at a moment when the chips 124 begin to come into contact with the bonding surface 140. From the moment of contact, and throughout the bonding process, each bonding head 134 imparts a downward force in the Z direction to facilitate the bonding of the chip with the bonding surface. More particularly, from the moment that the first chip of the plurality of chips contacts the bonding surface, until the moment that all of the chips have contacted and have been fully bonded to the bonding surface, there are varying magnitudes of force being applied in the Z direction by the bonding heads at different locations on the bonding surface. The combination of all the forces being applied by the bonding heads at a particular time imparts a net moment of force about the center of rotation CR of the carriage 142. The force applicators 116, being located at known positions relative to the surface 144 of the frame 120 of the carriage 142, can be actuated to impart a net moment of force about the center of rotation CR that is opposite in direction and equal in magnitude to the net moment of force caused by the bonding heads 134. As explained below, the net moment of force is a vector, which is understood to have directional components. Thus, “opposite in direction” should be understood to mean that the individual directional components (e.g., X, Y directions) of the vector representing the net moment of force applied by the force applicators opposes a corresponding individual directional component of the vector representing net moment of force applied by the bonding heads. That is, at any particular time during the bonding process, the force applicators 116 can be controlled, based on their locations relative to the center of rotation CR, to impart a force on the surface 144 of the frame 120 in the Z direction such that the summation of all of the forces imparted by the force applicators 116 creates a net moment of force about the center of rotation CR that counterbalances the net moment of force about the center of rotation CR being caused by a summation of all of the forces imparted by the bonding heads 134. Thus, after performing the step S202, the method proceeds to step S204 where, during the bonding of the plurality of chips to the bonding surface, a plurality of force applicators are actuated to collectively impart a net moment of force to the carriage about a center of rotation of the carriage that opposes a net moment of force collectively imparted to the carriage about the center of rotation of the carriage by the plurality of bonding heads.

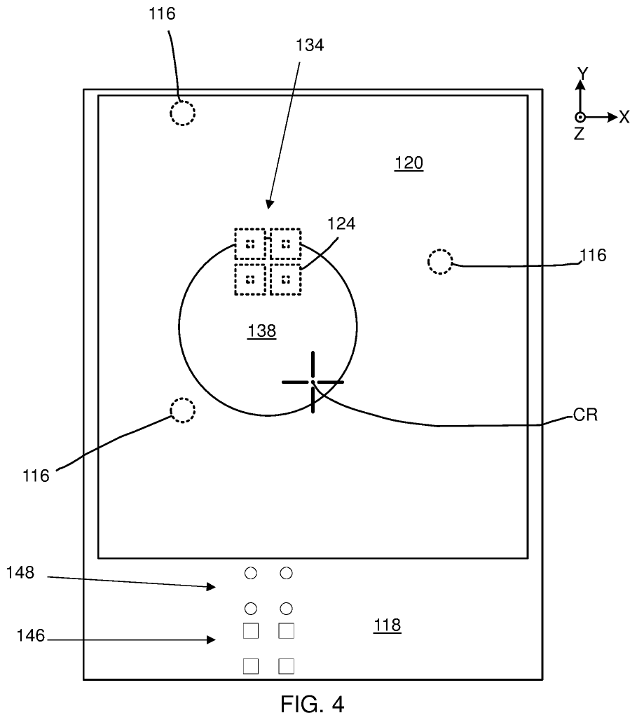

FIG. 4 shows a schematic top view of the area 160 of FIG. 1 at the same moment shown in FIG. 3C, with the bridge 132 omitted. That is, FIG. 4 shows one example time of the process of bonding a first set of chips. The top view of FIG. 4 best shows the location of the bonding heads 134, the chips 124, and the force applicators 116 in the X and Y dimensions relative to the center of rotation CR. As discussed above, each of the bonding heads 134 will apply a varying amount of force in the Z direction throughout the bonding process, but each bonding head applies the force at a different X/Y location on the bonding surface 140. Similarly, the force applicators 116 are each located at a different X/Y location above the surface 144 of the carriage 142 and, when actuated, apply a force in the Z direction on the surface 144. Each force imparted by a particular bonding head at a particular time contributes to the net moment of force about the center of rotation CR. The individual moment of force imparted by an individual bonding head is the cross product of a vector representing the magnitude of the force in the Z direction and a distance of the bonding head from the center of rotation CR. The individual moment of force imparted by an individual applicator is the cross product of a vector representing the magnitude of the force which is mostly in the Z direction and a distance of the force applicator from the center of rotation CR.

The moment of force imparted by an individual bonding head at a particular time may be represented by the following equation (1):

$${\vec{MF}}_{BHi} ( t ) = {\vec{F}}_{BHi} ( t ) \times {\vec{r}}_{BHi} \qquad Equation ( 1 )$$

In equation (1), \vec{MF}_{BHi}(t) is a vector representing the moment of force caused by a particular bonding head BHᵢ at a particular time t about the center of rotation CR of the carriage. \vec{F}_{BHi}(t) is a vector representing the bonding force applied by a particular bonding head BHᵢ at a particular time t. \vec{r}_{BHi} is a vector representing the location of the particular bonding head BHᵢ relative to the center of rotation CR of the carriage. In equation (1), i is a positive integer, e.g., i being 1 means BH₁ refers to bonding head 1 The time t may be from 1 ms to 1000 ms. Each of the vectors representing the bonding force and the location of the bonding head can be represented in terms of their component parts in the X, Y, and Z dimension. Because the force applied by the bonding heads is generally only in the Z direction, the X and Y component of the vector representing the bonding force for a particular bonding head may be assumed to be substantially 0 in most cases. As shown in equation (1), the moment of force caused by a particular bonding head at a particular time is the cross product of the vector representing the bonding force applied by the particular bonding head at the particular time and the vector representing the location of the particular bonding head at the same particular time.

The moment of force imparted by an individual force applicator at a particular time may be represented by the following equation (2):

$${\vec{MF}}_{Aj} ( t ) = {\vec{F}}_{Aj} ( t ) \times {\vec{r}}_{Aj} \qquad Equation ( 2 )$$

In equation (2), \vec{MF}_{Aj}(t) is a vector representing the moment of force caused by a particular force applicator Aⱼ at a particular time t about the center of rotation CR of the carriage. \vec{F}_{Aj}(t) is a vector representing the force applied by a particular force applicator Aⱼ at a particular time t. \vec{r}_{Aj} is a vector representing the location of the particular force applicator Aⱼ relative to the center of rotation CR of the carriage. In equation (2), j is a positive integer, e.g., j being 1 means A₁ refers to force applicator 1. The time t is the same as in equation (1). Each of the vectors representing the force applied by the force applicator and the location of the force applicator can be represented in terms of their component parts in the X, Y, and Z dimension. Because the force applied by the force applicator is generally only in the Z direction, the X and Y component of the vector representing the force applied by a particular force applicator may be assumed to be substantially 0 in most cases. As shown in equation (2), the moment of force caused by a particular force applicator at a particular time is the cross product of the vector representing the force applied by a particular force applicator at the same particular time and the vector representing the location of the particular force applicator at the same particular time.

The net moment of force caused by all of the bonding heads together at a particular time may be represented by the following equation (3). The net moment of force caused by all of the force applicators together at a particular time may be represented by the following equation (4):

$${\vec{MF}}_{BHnet} ( t ) = {\sum }_{i = 1}^{N} {\vec{F}}_{BH , i} ( t ) \times {\vec{r}}_{BH , i} \qquad Equation ( 3 )$$

$${\vec{MF}}_{Anet} ( t ) = {\sum }_{j = 1}^{M} {\vec{F}}_{A , j} ( t ) \times {\vec{r}}_{A , j} \qquad Equation ( 4 )$$

In equation (3) \vec{MF}_{BHnet}(t) is a vector representing the net moment of force about the center of rotation CR of all of the bonding heads together at a particular time t. N represents the total number of bonding heads. The number of bonding heads is provided above. Thus, N may be 2 to 300, 5 to 100, or 8 to 16, for example. In the example illustrated embodiments N is 4. Thus, as shown in Equation (3), the net moment of force about the center of rotation CR caused by all of the bonding heads at a particular time is the summation of the all the individual moments of force imparted by the individual bonding heads at the same particular moment of time. Similarly, in equation (4), \vec{MF}_{Anet}(t) is a vector representing the net moment of force about the center of rotation CR of all of the force applicators together at a particular time t. M represents the total number of force applicators. The number of force applicators is provided above. Thus, M may be 2 to 30, more preferably M is 3 to 5, for example. In the illustrated example embodiment M is 3. Thus, as shown in Equation (4), the net moment of force about the center of rotation CR caused by all of the force applicators at a particular time is the summation of the all the individual moments of force imparted by the individual force applicators at the same particular moment of time. Each of the vectors representing the net moment of force applied by the bonding heads and the net moment of force applied by the force applicators can be represented in terms of their component parts in the X, Y, and Z dimension.

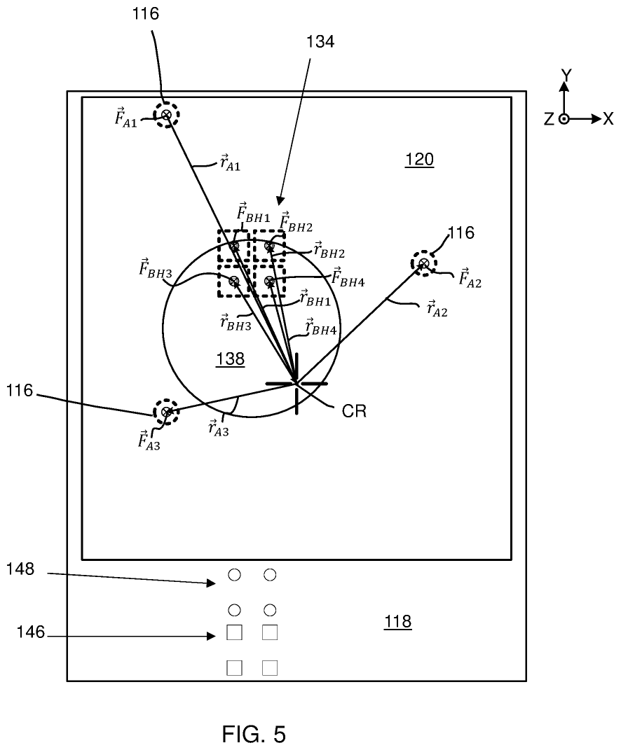

FIG. 5 shows the same top view of FIG. 4, but additionally shows the vectors representing the location of the bonding heads and force applicators. In the illustrated example embodiment, there are four bonding heads 134 and three force applicators 116. Each of the four bonding heads have a corresponding vector representing their location relative to the center of rotation CR and each of the three force applicators have a corresponding vector representing their location relative to the center of rotation CR. In FIG. 5, \vec{r}_{BH1} is a vector representing the location of the first bonding head, \vec{r}_{BH2} is a vector representing the location of the second bonding head, \vec{r}_{BH3} is a vector representing the location of the third bonding head, \vec{r}_{BH4} is a vector representing the location of the fourth bonding head. Similarly, in FIG. 5, \vec{r}_{A1} is a vector representing the location of the first force applicator, \vec{r}_{A2} is a vector representing the location of the second force applicator, 743 is a vector representing the location of the third force applicator. Furthermore, in FIG. 5, \vec{F}_{BH1} is a vector representing the force applied by the first bonding head, \vec{F}_{BH2} is a vector representing the force applied by the second bonding, \vec{F}_{BH3} is a vector representing the force applied by the third bonding head, \vec{F}_{BH4} is a vector representing the force applied by fourth bonding head, where all of the force vectors of the bonding heads are in the Z direction (i.e., into the page from the perspective of FIG. 5). Similarly, in FIG. 5, \vec{F}_{A1} is a vector representing the force applied by the first force applicator, \vec{F}_{A2} is a vector representing the force applied by the second force applicator, \vec{F}_{A3} is a vector representing the force applied by the third force applicator, where all of the force vectors of force applicators are in the Z direction (i.e., into the page from the perspective of FIG. 5).

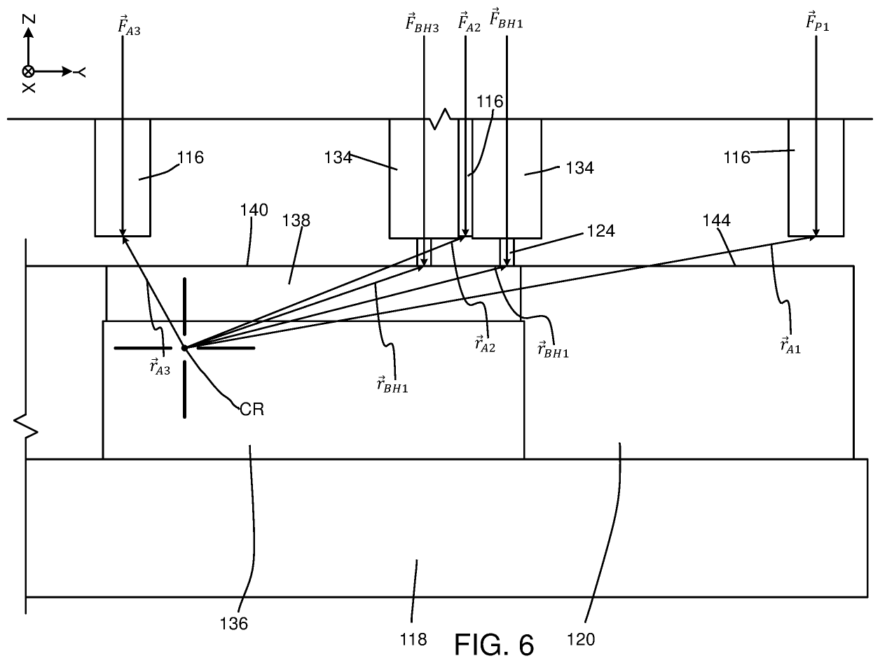

FIG. 6 shows a closer view of a portion of the bonding section at the same moment shown in FIG. 6, with the location and force vectors for the bonding heads and the force applicators shown. The reference characters representing the various force vectors and location vectors are the same as in FIG. 5. However, the side view shown in FIG. 6 shows the Z dimension direction of the force vectors that is not seen in the top view of FIG. 5. FIGS. 5 and 6, taken together, fully illustrate the location vectors \vec{r}_{BH1}, \vec{r}_{BH2}, \vec{r}_{BH3}, \vec{r}_{BH4}, \vec{r}_{BH4}, \vec{r}_{A1}, \vec{r}_{A2}, \vec{r}_{A3} and the force vectors \vec{F}_{BH1}, \vec{F}_{BH2}, \vec{F}_{BH3}, \vec{F}_{BH4}, \vec{F}_{A1}, \vec{F}_{A2}, \vec{F}_{A3} in the X, Y, and Z dimensions.

In order to minimize or eliminate the tilt of the carriage 242 about the center of rotation CR, step S202 may include balancing the net moment of force \vec{MF}_{BHnet} caused by the bonding heads by actuating the force applicators to cause a net moment of force \vec{MF}_{Anet} that is equal and opposite to the net moment of force \vec{MF}_{BHnet} caused by the bonding heads. This balancing step may be formed repeatedly/continuously over during the time period in which it takes to fully bond all of the chips held by the bonding heads to the bonding surface. That is, the balancing step may be repeatedly/continuously performed from the moment one of the chips of the set of chips being bonded contacts the bonding surface until the moment that all of the chips for the set of chips being bonded are fully bonded to the bonding surface. In one example embodiment, the time period from the moment of contacting one of the chips to the bonding surface to fully bonding all of the chips is 300 ms. In this period of time, the balancing step may be performed every 1 ms, for example.

The balancing step may be performed by instructing the force applicators to apply the appropriate amount of force that will create the net moment of force \vec{MF}_{Anet} that is equal and opposite to the net moment of force \vec{MF}_{BHnet}. This balancing can be represented by the following equation (5).

$$\vec{0} = {\vec{MF}}_{BHnet} ( t ) + {\vec{MF}}_{Anet} ( t ) = {\sum }_{i = 1}^{N} {\vec{F}}_{BHi} ( t ) \times {\vec{r}}_{BHi} + {\sum }_{j = 1}^{M} {\vec{F}}_{Aj} ( t ) \times {\vec{r}}_{Aj} \qquad Equation ( 5 )$$

Equation (5) represents the ideal circumstance when the net moment of forces are exactly balanced to zero, in which case tilt of the carriage is completely eliminated. However, in a case of minimizing tilt within an acceptable level of error, the magnitude of the net moment of force imparted by the plurality of force applicators (i.e., the magnitude of the vector \vec{MF}_{Anet}) may be ±5% of the magnitude of the net moment of force imparted by the plurality of bonding heads (i.e., the magnitude of the vector \vec{MF}_{BHnet}). More preferably the magnitude of the net moment of force imparted by the plurality of force applicators is ±2% of the magnitude of the net moment of force imparted by the plurality of bonding heads, more preferably ±1%, and more preferably ±0.5%.

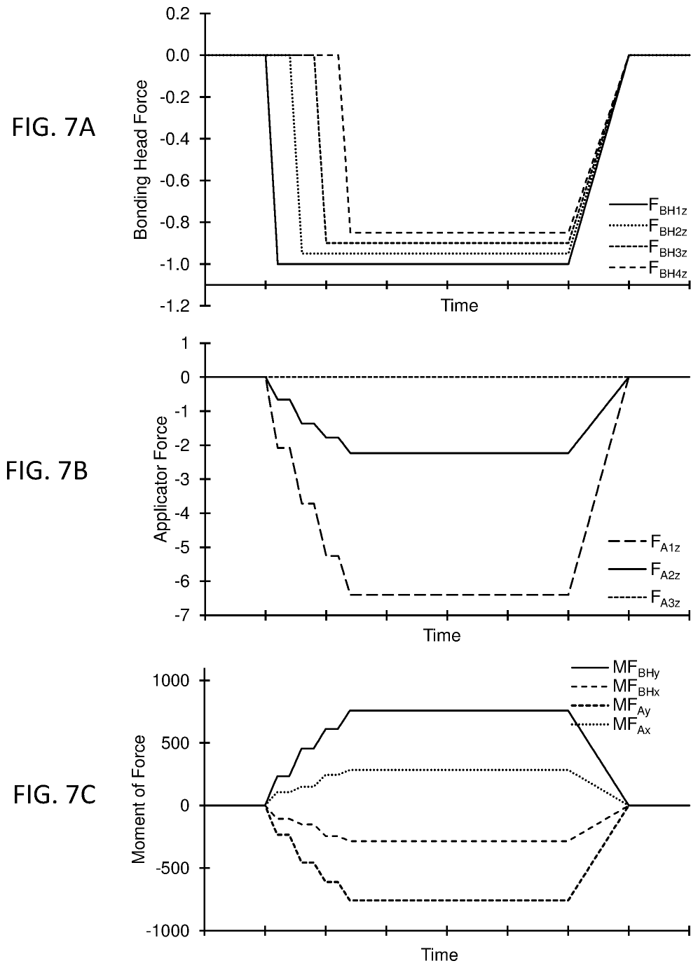

FIGS. 7A-7C are timing charts showing the forces and moment of force imparted by the bonding heads and the force applicators in accordance with an example embodiment. Specifically, FIG. 7A is a timing chart of the z component of the force (\vec{F}_{BHi}(t)=\vec{F}_{BHiz}(t)\hat{z}) applied by each bonding head during the bonding process, FIG. 7B is a timing chart showing the z component of the force (\vec{F}_{Aj}(t)=\vec{F}_{Aiz}(t)\hat{z}) applied by the force applicators during a bonding process (using arbitrary units), and FIG. 7C is a timing chart showing the net moment of force (\vec{MF}_{BHnet}(t)=\vec{MF}_{BHx}(t)\hat{x}+\vec{MF}_{BHy}(t)ŷ) imparted by all of the bonding heads and the net moment of force (\vec{MF}_{Anet}(t)=\vec{MF}_{Ax}(t)\hat{x}+\vec{MF}_{Ay}(t)ŷ) imparted by all of the force applicators for both the X and Y dimensions. The x-axis in each of FIGS. 7A to 7C is the same and represents time over the course of the same bonding process. That is, the same point along the x-axis in each of FIGS. 7A to 7C represents the same instant in time. Thus, by comparing FIGS. 7A to 7C, one can observe what is occurring with respect to the forces applied and the net moment of forces applied at the same times during a single bonding process. The y-axes in FIGS. 7A and 7B is force and the y-axis in FIG. 7C is net moment of force. FIGS. 7A to 7C show one example embodiment in which the four bonding heads and the three applicators are present for a particular bonding process. The force and moment timing diagrams shown in FIGS. 7A-C are exemplary and are designed to illustrate the moments and forces being used on how they are related. However, while the illustrated curves would be different depending on the bonding location, depending on how many bonding heads are present, depending how many force applicators are present, etc., the principle illustrated would be the same.

FIG. 7A includes four types of lines to represent the forces applied by the four different bonding heads of the example embodiment. As indicated in the key on FIG. 7A, the solid line represents the force applied by bonding head 1 (\vec{F}_{BH1z}), the small dotted line represents the force applied by bonding head 2 (\vec{F}_{BH2z}), the large dotted line represents the force applied by bonding head 3 (\vec{F}_{BH3z}), and the dashed line represents bonding the force applied by head 4 (\vec{F}_{BH4z}). As shown in FIG. 7A, at the beginning of the time scale, all four of the bonding heads are not imparting any force. In the example embodiment shown in FIG. 7A, bonding head 1 provides a force first, followed by bonding head 2 applying a smaller force than bonding head 1, followed by bonding head 3 applying a smaller force that bonding head 1 and 2, and finally following by bonding head 4 applying a smaller force than bonding heads 1, 2, and 3. The forces being applied by the four bonding heads are held constant until they simultaneously begin reducing the force until returning to 0 at the completion of the bonding of the chips.

FIG. 7B includes three types of lines representing the force applied by the three different force applicators of the example embodiment. As indicated in the key on FIG. 7B, the dotted line represents the force applied by force applicator 1 (F_{A1z}), the solid line represents the force applied by force applicator 2 (F_{A2z}), and the dashed line represents the force applied by force applicator 4 (F_{A3z}). As noted above, FIG. 7B shows what forces the three force applicators are applying at the same time period as in FIG. 7A. As shown in FIG. 7B, at the beginning of the time scale, all three of the force applicators are not imparting any force. In the example embodiment shown in FIG. 7B, the first force applicator A1 is not needed in the example embodiment and thus is constantly 0 throughout the time period. The forces F_{A2z} and F_{A3z} applied by force applicators A2 and A3 increase along with time based on their location relative to the center of rotation CR of the carriage in order to balance the moment of force created by the bonding heads. As with the bonding heads, the force applied by the force applicators A2 and A3 gradually decrease toward the end of the bonding process.

FIG. 7C includes four types of lines to represent the net moment of force applied about the center of rotation CR of the carriage by all of the bonding heads together and all of the force applicators together for both the X and Y dimensions. The solid line represents the net moment of force applied by all of the bonding heads together in the Y dimension (MF_{BHy}). The larger spaced dashed line represents the net moment of force applied by all of the bonding heads together in the X dimension (MF_{BHx}). The smaller spaced dashed line represents the net moment of force applied by all of the force applicators together in the Y dimension (MF_{Ay}). The dotted line represents the net moment of force applied by all of the force applicators together in the X dimension (MF_{Ax}). As shown in FIG. 7C, across the bonding process at any particular time, the net moment of force imparted by the bonding heads in X and Y dimensions is opposed by an equal and opposite net moment of force applied by the force applicators. That is, the line MF_{BHy} is equal and opposite to the line MF_{Ay} and the line MF_{BHx} is equal and opposite to the line MF_{Ax}. Accordingly, when the net moment for force caused by the bonding heads increases, the net moment of force caused by the force applicators increases in the opposite direction for the X and Y dimensions. Similarly, when the net moment for force caused by the bonding heads decreases, the net moment of force caused by the force applicators decreases in the opposite direction for the X and Y dimensions. By balancing the net moments of force throughout the entire bonding process, tilting of the carriage is prevented or minimized.

The amount of force that each individual force applicator should apply to counteract the net moment of force at a particular time can be based entirely on predetermined information regarding the bonding forces or can be based on a combination of predetermined information and sensor information gathered during the bonding process. The predetermined information is specifically predetermined information regarding when each individual bonding head will contact the bonding surface and how much force is applied by each individual bonding head through the bonding of a particular chip. As part of instructing the bonding heads to perform the bonding process, the movement in Z direction toward the bonding surface as well as the amount of force being applied by the bonding head is known in advance at every moment during the bonding process. That is, for each bonding head, the controller has information regarding when the chip will contact the bonding surface, how much force is applied at that moment of contact, and how much force is applied during the bonding until the bonding is complete. The center of rotation of the carriage is also known based the weight and each center of mass of the components of the carriage itself as well as all the components currently on the carriage, including any chips that have been bonded in a previous bonding process on the substrate currently being worked upon. Additionally, the location of each bonding head relative to the center of rotation is known. Thus, at any particular time, the controller has information about the moment of force that is being applied by each of the individual bonding heads, as well as the net moment of force being applied by all of the bonding heads together. The location of the force applicators relative to the center of rotation is also known. Based on all of this information, the controller can receive or determine how much force each individual force applicator should apply on the carriage such that the equation (5) can be satisfied throughout the bonding process. That is, in one example embodiment, based only on the predetermined information, the controller can cause each individual force applicator to apply a particular force repeatedly/continuously through the chip bonding process so that the equation (5) is satisfied throughout the bonding process. Equation (5) may be solved for each of \vec{F}_{Aj}(t) assuming that \vec{F}_{BHi}(t), \vec{r}_{BHi}, and \vec{r}_{Aj} are known. The values of \vec{r}_{BHi}, and \vec{r}_{Aj} are fixed for each particular bonding process and \vec{F}_{BHi}(t) maybe measured and/or predetermined. Depending on the number of force applicators M, equation (5) may be an underdetermined system of equations in which case one or more of the force applicators may be set to zero, an arbitrary value, or to a function of the other force applicator values. In most instances only the z components of \vec{F}_{BHi}(t) and \vec{F}_{Aj}(t) needs to be considered, the impact of the x and y components of these forces will be relatively small compared to the z component. In an embodiment, the space surrounding the center of rotation is divided into equal M angular sectors centered on each force applicator. The center of the bonding heads is located in a particular angular sector among the M angular sectors or a fraction of M angular sectors. The force applicator in that particular angular sector may be set to zero while the others are determined using equation (5). The value for force applicators may also be limited by the range of the force that the force applicators can supply. In most instances only two force applicators will need to be used at any one time. If the forces are unidirectional and in the same direction then two force applicators selected may be on the opposite side of the center of rotation CR relative to the bonding heads.

In another example embodiment, rather than relying on the predetermined information regarding what force will be applied by each bonding head throughout the bonding process, the forces being applied by the bonding heads at a particular moment can be determined based on measurements. In this example embodiment, much of the same information as in the above-noted embodiment is used, such as the location of the bonding heads, the location of the force applicators, and the center of rotation. However, rather than determining the amount of force that should be applied by the force applicators based on the predetermined bonding head forces for a particular time, a sensor may be used to measure the current or voltage of the bonding force actuator in the z direction of each bonding head at the particular time. The bonding force in the z direction may also be estimated based on multiple control values and/or measured values of multiple actuators. This measurement can be correlated with a force to determine the bonding force that is currently being applied by each bonding head. That is, the sensor allows the controller to determine what the actual forces are being applied by the bonding heads and not just what is expected. The bonding force information of each individual bonding head at the particular time can be used in the same manner as the predetermined force information is used in the above embodiment. That is, throughout the bonding process, the measurement of the current(s) and/or voltage(s) can be used to determine bonding forces, which can then be used to determine net moment of force caused by the bonding heads. This information can then be used to determine how much force each force applicator should apply on the carriage to satisfy equation (5). While the example embodiment using a sensor to determine actual bonding forces requires additional sensors and feedback, it has an advantage of accounting for factors that may have caused deviations from the expected bonding forces.

After all of the chips 124 on the bonding heads 134 have been fully bonded to bonding surface, all of the bonded chips 124 are released from their bonding heads 134. That is, with the chips being bonded on one side of the chip to the bonding surface, the bonding heads may release the opposite side of the chip being held by the bonding heads. Once released, the bonding process has been completed. At this point, the bonding process can be repeated using more chips.

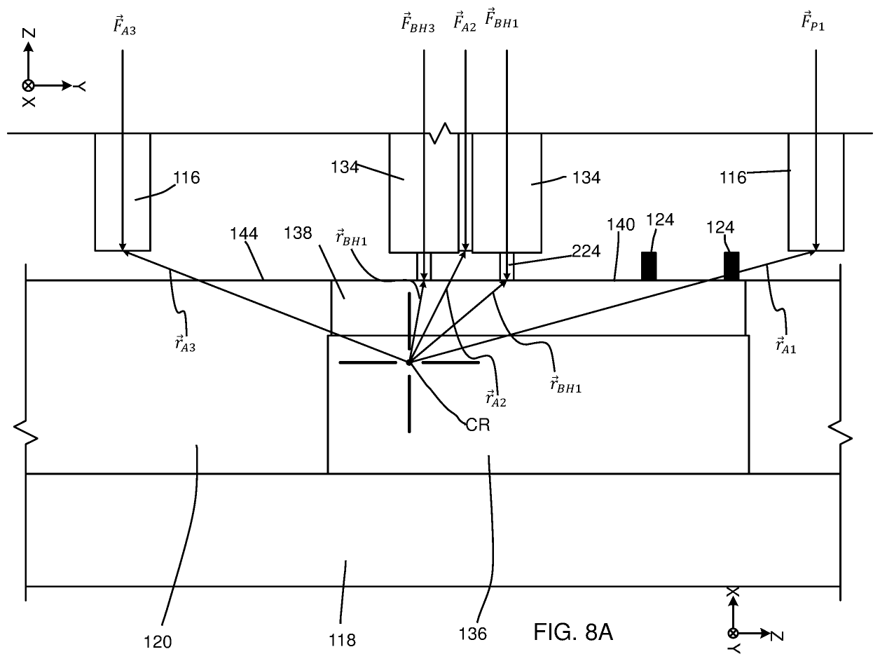

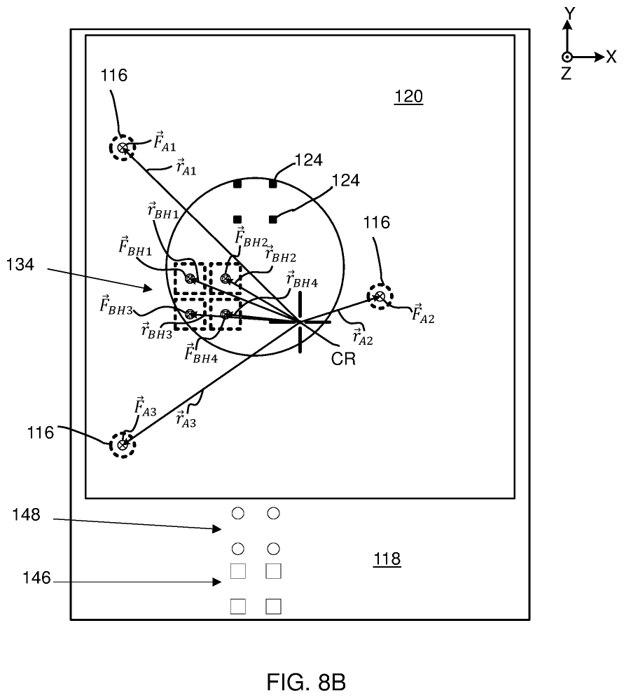

FIG. 8A is a schematic close-up view of a portion of the bonding section 106 (similar to FIG. 6) during a subsequent bonding process where a second set of 224 chips are being bonded to the bonding surface after completion of the first bonding process. FIG. 8B shows a schematic top view of the same moment shown in FIG. 8A. As shown in FIGS. 8A and 8B, the first set of chips 124 from the prior bonding process is already bonded to the bonding surface 140. At the moment shown in FIGS. 8A and 8B, a second set of chips 224 are just beginning to come into contact with the bonding surface 140. However, because this second set of chips 224 are bonded to the bonding surface 140 at locations different than the bonding locations of the first set of chips 124, the bonding heads 134 and chips 224 are located at different X and Y dimension positions relative to the bonding surface 140 as compared to the bonding head/chip locations during the prior bonding process. That is, the carriage 142 has been moved so that the bonding heads 134 and the second set of chips 224 are in the proper predetermined X and Y positions to bond the chips 224 where desired. Similarly, because the force applicators 116 are mounted to the bridge 132 in the illustrated embodiment, the force applicators 116 are also at different X and Y dimension locations relative to the bonding surface 140 as compared to the location of the force applicators 116 during the prior bonding process. Thus, the location of the force applicators in the second bonding process shown in FIGS. 8A and 8B is different from the location of the force applicators in the first bonding process shown in FIGS. 3 to 6. In the example embodiment shown in FIGS. 8A and 8B all three of the force applicators are facing the surface 144. However, as noted above, in certain instances, at least two of the force applicators may be facing the surface 144 while other force applicators may not be facing the surface 144. In such a case, the force applicators not facing the surface 144 would not be used as part of the balancing of the moment of force. The center of rotation CR also changes a small amount depending on the mass of the chips bonded in the previous step.

The process of bonding the second set of chips 224 the same as the method 200 described as above for bonding the first set of chips 124. Thus, during the bonding of the second set of chips 224, the net moment of force about the center of rotation that is imparted as the bonding heads bond the chips 224 to the bonding surface 140 is similarly balanced by the force applied by the applicators 116. The difference is that the individual moments of force about the center of rotation caused by each of the bonding heads and each of the force applicators is different because the X and Y dimension locations are different. This is illustrated in FIGS. 8A and 8B in that the vectors representing the location of the bonding heads 134 and the vectors representing the location of the force applicators 116 are different from the location vectors in FIGS. 5 and 6. However, the balancing of the net moments of force about the center of rotation to satisfy equation (5) is the same, using the same process described above. In other words, no matter where the bonding heads and force applicators are located, the same process described above to satisfy equation (5) is performed.

Once the second set of chips 224 is completely bonded to the bonding surface 140, and the second set of chips 224 have been released, the process may be repeated until all of the desired number of chips have been bonded to the bonding surface. For example, hundreds, thousands, or tens of thousands of chips can be bonded to the bonding surface. While four bonding heads are illustrated in the example embodiment, as many as 300 bonding heads can be used in a single bonding process. The greater the number of bonding heads, the more chips can be bonded during the same bonding process. Even in a case where the number of bonding heads are many times greater than the number of force applicators (e.g., up to 100 times more), equation (5) can still be satisfied using the above-described method. In such a case where there are for example 300 bonding heads and three force applicators, at any particular time in the bonding process, the three force applicators can be instructed to apply the necessary amount of force to counterbalance the net moment of force caused by the 300 bonding heads.

After process of bonding chips to bonding surface is complete (which may include many cycles of the bonding method 200 to bond hundreds, thousands, or tens of thousands of chips), the product substrate 138 is removed from the chip bonding section 106 by for example the transfer robot 126 or the like. The product substrate may then be subjected to an annealing process (which may include one or both of heat and pressure) in which the hybrid bonding process is completed. The product substrate may be subjected to additional processes in which additional chips are added to the product substrate before or after the annealing process. The product substrate may then be subjected to additional processes, such as: singulation, testing, encapsulation, etc., which are used to produce a plurality of articles from the product substrate.

As noted above, while all of the force applicators are illustrated as being coupled to the bridge in FIGS. 1, 3A-3C, and 6, in other embodiments one or more or all of the force applicators may be coupled to the surface 144 of the frame 120. FIG. 9 shows a side view of an example embodiment where the force applicators 116 are on the frame 120 with the actuating end 122 facing the surface 150 of the bridge 132. In the case that any or all of the force applicators are coupled to the frame 120, the force applicators would apply the force onto the surface 150 of the bridge 132 instead of the surface 144 of the frame 120. Because the bridge 132 is stationary, the actuation for the force applicators 116 to impart force upon the surface 150 of the bridge 132 would still cause the force applicators 116 to impart a moment of force about the center of rotation CR of the carriage 142. Additionally, because the force applicators are carried by the carriage 142, the force applicators would contribute to location of the center of rotation CR of the carriage 142. Thus, the center of rotation CR may be different than in the embodiment where the force applicators are mounted to the bridge 132. Furthermore, when the force applicators are attached to the carriage 142, the location of the force applicators in the X and Y dimensions will always be the same relative to the bonding surface no matter where the bonding heads are bonding chips to the bonding surface. That is, in such an embodiment, even when the carriage is moved so that the bonding heads are relocated to bond chips at another location on the bonding surface, the force applicators will move with the carriage and maintain their position relative to the bonding surface. Regardless, the method described above to balance the net moments of force during the bonding process to satisfy equation (5) is the same.

Note that not all of the activities described above in the general description or the examples are required, that a portion of a specific activity may not be required and that one or more further activities can be performed in addition to those described. Still further, the order in which activities are listed is not necessarily the order in which they are performed. While the above description, was described in the context of hybrid bonding process, other bonding processes may be used such as soldering, flip-chip bonding, ball grid array bonding, or another process that used to form a plurality of electrical connections between chips.

Benefits, other advantages, and solutions to problems have been described above with regard to specific implementations. However, the benefits, advantages, solutions to problems, and any feature(s) that can cause any benefit, advantage, or solution to occur or become more pronounced are not to be construed as a critical, required, or essential feature of any or all the claims.

The specification and illustrations of the implementations described herein are intended to provide a general understanding of the structure of the various implementations. The specification and illustrations are not intended to serve as an exhaustive and comprehensive description of all of the elements and features of apparatus and systems that use the structures or methods described herein. Separate implementations can also be provided in combination in a single implementation, and conversely, various features that are, for brevity, described in the context of a single implementation, can also be provided separately or in any subcombination. Further, reference to values stated in ranges includes each and every value within that range. Many other implementations can be apparent to skilled artisans only after reading this specification. Other implementations can be used and derived from the disclosure, such that a structural substitution, logical substitution, or another change can be made without departing from the scope of the disclosure. Accordingly, the disclosure is to be regarded as illustrative rather than restrictive.

What is claimed is:

1. A method for bonding chips, comprising:
actuating a plurality of bonding heads to cause a plurality of chips to bond to a bonding surface supported by a carriage; and
during the bonding of the plurality of chips to the bonding surface, actuating a plurality of force applicators to collectively impart a net moment of force to the carriage about a center of rotation of the carriage that opposes a net moment of force collectively imparted to the carriage about the center of rotation of the carriage by the plurality of bonding heads.

2. The method of claim 1,
wherein actuating the plurality of bonding heads to cause the plurality of chips to bond to the bonding surface occurs over a bonding period, and
wherein the method further comprises, throughout the bonding period, repeatedly actuating the plurality of force applicators to impart the net moment of force that opposes the net moment of force imparted by the plurality of bonding heads.

3. The method of claim 1,
wherein the plurality force applicators are actuated such that the net moment of force imparted by the plurality of force applicators counteracts the net moment of force imparted by the plurality of bonding heads.

4. The method of claim 1,
wherein the plurality force applicators are actuated such that the net moment of force imparted by the plurality of force applicators negates the net moment of force imparted by the plurality of bonding heads.

5. The method of claim 1,
wherein a magnitude of the net moment of force imparted by the plurality of force applicators is ±5% of a magnitude of the net moment of force imparted by the plurality of bonding heads.

6. The method of claim 1,
wherein a magnitude of the net moment of force imparted by the plurality of force applicators is equal to a magnitude of the net moment of force imparted by the plurality of bonding heads.

7. The method of claim 1,
wherein the actuating of the plurality of bonding heads occurs contemporaneously with the actuating of the plurality of force applicators.

8. The method of claim 1,
wherein the net moment of force imparted by the plurality of force applicators is a summation of a moment of force imparted by each force applicator of the plurality of force applicators to the carriage about the center of rotation of the carriage, and
wherein the net moment of force imparted by the plurality of bonding heads is a summation of a moment of force imparted by each bonding head of the plurality of bonding heads to the carriage about the center of rotation of the carriage.

9. The method of claim 1,
wherein the plurality of force applicators includes 2 to 30 force applicators.

10. The method of claim 1,
wherein the plurality of force applicators includes three force applicators.

11. The method of claim 1,
wherein the plurality of bonding heads includes 2 to 300 bonding heads.

12. The method of claim 1,
wherein each force applicator of the plurality of force applicators is configured to act upon an actuating surface while at a distance from the actuating surface.

13. The method of claim 12,
wherein each force applicator of the plurality of force applicators includes a nozzle configured to dispense a compressed gas, and
wherein actuating the plurality of force applicators includes dispensing the compressed gas from at least two force applicators of the plurality of force applicators against the actuating surface.

14. The method of claim 12,
wherein each force applicator of the plurality of force applicators includes an electromagnet, and
wherein actuating the plurality of force applicators includes actuating the electromagnet of at least two force applicators of the plurality of force applicators towards the actuating surface.

15. The method of claim 12,
wherein the actuating surface is a surface of the carriage or is a surface of a bridge above the carriage.

16. The method of claim 1, further comprising
actuating the plurality of bonding heads to cause another plurality of chips to bond to the bonding surface; and
during the bonding of the other plurality of chips to the bonding surface, actuating the plurality of force applicators to collectively impart a net moment of force to the carriage about the center of rotation of the carriage that opposes a net moment of force collectively imparted to the carriage about the center of rotation of the carriage by the plurality of bonding heads
wherein a location of the center of rotation of the carriage during the bonding of the other plurality of chips is different than a location of the center of rotation of the carriage during the bonding of the plurality of chips.

17. The method of claim 1, wherein the bonding surface is a surface of a substrate.

18. The method of claim 1, wherein the bonding surface is a surface of one or more chips.

19. A system for bonding chips, comprising:
a plurality of bonding heads;
a plurality of force applicators;
a carriage having a center of rotation;
one or more processors; and
one or more memories storing instructions, when executed by the one or more processors, causing the system to:
actuate the plurality of bonding heads to cause a plurality of chips to bond to a bonding surface supported by the carriage; and
during the bonding of the plurality of chips to the bonding surface, actuate the plurality of force applicators to collectively impart a net moment of force to the carriage about the center of rotation of the carriage that opposes a net moment of force collectively imparted to the carriage about the center of rotation by the plurality of bonding heads.

20. A method of manufacturing a plurality of articles, comprising:
actuating a plurality of bonding heads to cause a plurality of chips to bond to a bonding surface of a substrate supported by a carriage;
during the bonding of the plurality of chips to the bonding surface, actuating a plurality of force applicators to collectively impart a net moment of force to the carriage about a center of rotation of the carriage that opposes a net moment of force collectively imparted to the carriage about the center of rotation of the carriage by the plurality of bonding heads; and
singulating the substrate to produce the plurality of articles.
